(19) United States
(12) Patent Application Publication
(10) Pub. No.: US 2023/0021394 A1
(43) Pub. Date: Jan. 26, 2023

(54) METHOD FOR LARGE SURFACE COATING BASE ON CONTROL OF THIN FILM STRESS AND COATING STRUCTURE USEOF

(71) Applicant: KOMICO LTD., Anseong-si (KR)

(72) Inventors: Hong Rae Wang, Anseong-si (KR); Yeong Jun Son, Anseong-si (KR); Yo Han Ryu, Anseong-si (KR); In Haeng Lee, Anseong-si (KR); In Seop Byeon, Anseong-si (KR); Kyung Seung Koo, Anseong-si (KR); Jin Woo Hahn, Anseong-si (KR); Yong Soo Lee, Anseong-si (KR); Jae Ho Byun, Anseong-si (KR)

(21) Appl. No.: 17/476,412

(22) Filed: Sep. 15, 2021

(30) Foreign Application Priority Data
Jul. 19, 2021 (KR) 10-2021-0094142

(51) Int. Cl. C23C 28/04; H01J 37/32; C23C 14/08; C23C 14/22; C23C 16/50; C23C 16/40; C23C 14/34

(52) U.S. Cl. CPC C23C 28/042; H01J 37/32495; C23C 14/081; C23C 14/221; C23C 16/50; C23C 16/403; C23C 14/34; C23C 16/405; C23C 14/083

(57) ABSTRACT

Disclosed is a thin film stress control-based coating method for large-area coating. The method uses a two-step coating process in which a first coating layer that is a relatively low-hardness layer is primarily formed on a base member and a second coating layer that is a relatively high-hardness layer is secondarily formed on the first coating layer. The method can form a high-density coating structure that is hardly peeled off over a relatively large area compared to conventional coating methods by suppressing internal stress of the coating layers of the coating structure. Further disclosed is a coating structure manufactured by the same method.

### CROSS-REFERENCE TO RELATED APPLICATION

The present application claims priority to Korean Patent Application No. 10-2021-0094142 filed on Jul. 19, 2021, the entire contents of which is incorporated herein for all purposes by this reference.

### BACKGROUND OF THE INVENTION

### 1. Field of the Invention

The present disclosure relates to a thin film stress control-based coating method for large-area coating and a coating structure produced through the same method. More particularly, the present disclosure relates to a thin film stress control-based coating method for large area coating, the method being capable of forming a coating layer that will not easily peel by controlling stress applied to a coating layer when coating the surface of a large-area base member so that the coating layer can have corrosion resistance even in plasma or a strong corrosive atmosphere, and also relates to a coating structure produced through the same method.

### 2. Description of the Related Art

Integrated circuit devices such as semiconductor devices and display devices are manufactured through etching and deposition processes in in a high-density plasma environment in a chamber. Therefore, in apparatuses performing an etching process in a high-density plasma environment, parts that are exposed to plasma in their chamber are easily corroded by the plasma.

In addition, when manufacturing three-dimensional (3D) semiconductor devices to increase the degree of integration, a specific region must be quickly etched and removed in a short time. In this case, an etchant having a strong corrosive property is used, and the etchant may cause corrosion of parts disposed in the chamber.

As such, since the parts disposed in a chamber are etched and corroded under high-density plasma or in a strong corrosive atmosphere, surface-coating materials fall off and contaminate integrated circuit devices being manufactured. Therefore, it is necessary to coat the parts in a chamber with a corrosion-resistant coating material.

To solve such a problem, a related art document, Korean Patent Application Publication No. 10-2017-0021103 (published on Feb. 27, 2017), discloses a method of forming a coating film for a semiconductor device manufacturing chamber, the method including: (i) preparing a base member; (ii) forming a seed layer containing Y₂O₃₋ₓ (0<x<1) on the base member; (iii) forming a high-speed deposition layer containing Y₂O₃, (1<x<3) on the seed layer to provide a coating film; and (iv) heat-treating the coating film.

In addition, Korean Patent No. 10-1961411 (published on Mar. 22, 2019) describes a method of coating a chamber used to manufacture a large-area OLED panel, the method including: (i) preparing a base member; (ii) providing a buffer layer comprising Zr₂O or Y₂O₃ on the base member through an APS or SPS process, and (iii) providing a coating layer comprising YAG on the buffer through another APS or SPS process.

In addition, Korea Patent No. 10-2259919 (published on Jun. 1, 2021) discloses a method of coating a chamber, the method including: (i) preparing a base member comprising at least one material selected from the group consisting of SiC, SiO₂ and Al₂O₃; (ii) providing a first coating layer comprising SiOₓ (0.1≤x≤2) or AlO_{y}(0.1≤y≤1.5) on the base member; (iii) providing a second coating layer comprising YO_{z} (0.1≤z≤1.5) on the first coating layer; (iv) forming a laminate in which the first coating layer and the second coating layer are alternately laminated; and (v) heat-treating the laminate to form a crystalline single layer through a solid phase reaction between the first coating layers and the second coating layers.

The related art documents disclose a technique for manufacturing a coating member having corrosion resistance to plasma or a strong corrosive atmosphere by forming the first coating layer and the second coating layer on the base member. In the case of the conventional coating methods described above, when they are used to coat small specimens, defective coatings that result in peeling of coatings are not likely to occur because there is only little stress on coated thin films. However, when the methods are used to form a high-density coating film with no pores on a large-area component (for example, a substrate or window in a chamber), there is a problem in that the coated film is easily damaged due to the inherent internal tensile or compressive stress of the coated film although an external force is not applied to the coated film.

For this reason, there is a need for a new coating method capable of forming a high-density coating film that is not easily peeled off by controlling the internal tensile or compressive stress of the coating film and a coating structure produced through the same method.

### CITATION LIST

### Patent Literature

(Patent Literature 1) Korean Patent Application Publication No. 10-2017-0021103(published on Feb. 27, 2017)

(Patent Literature 2) Korean Patent No. 10-1961411 (published on Mar. 22, 2019)

(Patent Literature 3) Korean Patent No. 10 2017-2259919 (published on Jun. 1, 2021)

### SUMMARY OF THE INVENTION

The present disclosure has been made to solve the problems occurring in the conventional arts, and an objective of the present disclosure is to provide a coating method capable of forming, on a base member, a high-density large-area coating layer that is not easily peeled off by controlling stress occurring in the coating layer and which has high corrosion resistance even in a plasma or a strong corrosive atmosphere.

Another objective of the present disclosure is to provide a coating structure produced through the same coating method.

One aspect of the present disclosure provides a thin film stress control-based coating method for large-area coating, the method including: preparing a base member; forming a first coating layer having a first hardness by depositing inorganic particles on the base member at a predetermined deposition rate; and forming a second coating layer having a second hardness by depositing inorganic particles on the first coating layer at a lower deposition rate than the predetermined deposition rate at which the first coating layer is formed.

As one embodiment, the first coating layer and the second coating layer may be formed by plasma chemical vapor deposition, sputtering deposition, or electron beam deposition.

In addition, as one embodiment, the inorganic particles may include oxides, fluorides, fluorinated oxides, nitrides, oxynitrides, and carbides of at least one metal selected from among Al, Y, Ti, W, Zn, Si, Mo, and Mg.

In addition, as one embodiment, the base member may have a diameter in a range of 10 to 80 cm and an area of 78.5 to 5,024 cm².

In addition, as one embodiment, the base member includes at least one selected from among oxides, fluorides, fluorinated oxides, nitrides, oxynitrides, and carbides of at least one material selected from among Al, Y, W, Zn, Si and Mo.

In addition, as an embodiment, the foaming of the first coating layer and the foaming of the second coating layer may be performed at a temperature in a range of 100° C. to 600° C.

In addition, as one embodiment, the first coating layer may be formed at a deposition rate of 2 to 5 Å/sec, and the second coating layer may be formed at a deposition rate of 0.5 to 1.5 Å/sec.

In addition, as one embodiment, electric power applied to an ion-assisting deposition apparatus may be 200 to 750 W when forming the first coating layer and may be 800 to 1500 W when forming the second coating layer. In addition, as one embodiment, when forming the first coating layer and the second coating layer, a gas used to form the first coating layer and the second coating layer may be at least one selected from among Ar, O₂ and N₂ gas and may be supplied at a flow rate of 5 to 100 standard cubic centimeters per minute (sccm).

Another aspect of the present disclosure provides a thin film stress control-based coating structure for large-area coating, the structure including: a first coating layer having a first hardness 5 to 8 GPa that is relatively low and being formed by depositing organic particles on a base member 45; and a second coating layer having a second hardness of 10 to 13 GPa that is relatively high and being formed by depositing inorganic particles on the first coating layer.

In addition, as one embodiment, the base member may have a diameter in a range of 10 to 80 cm and an area of 78.5 to 5,024 cm².

In addition, as one embodiment, the base member includes at least one selected from among oxides, fluorides, fluorinated oxides, nitrides, oxynitrides, and carbides of at least one material selected from among Al, Y, W, Zn, Si and Mo. In addition, as one embodiment, the inorganic particles may include at least one selected from among oxides, fluorides, fluorinated oxides, nitrides, oxynitrides, and carbides of one selected from among Al, Y, Ti, W, Zn, Si, Mo, and Mg.

In addition, as an embodiment, the first and second coating layers have a total thickness of 1 to 20 μm.

In addition, as an embodiment, the first and second coating layers may have the same crystalline phase.

In addition, as an embodiment, the first and second coating layers may have a cubic crystalline phase.

In addition, as an embodiment, the first and second coating layers may have a cubic crystalline phase.

In addition, as an embodiment, the thickness of the second coating layer may account for a proportion of 80% to 90% in the total thickness of the composite coating structure including the first coating layer and the second coating layer.

In addition, as an embodiment, the composite coating structure including the first coating layer and the second coating layer may have an XRD crystallization ratio of 80% to 84%.

In addition, as an embodiment, the first coating layer may have an adhesion strength of 10 to 13 N, and the second coating layer may have an adhesion strength of 6 to 8 N.

In addition, as an embodiment, the composite coating structure including the first coating layer and the second coating layer may have an overall hardness of 8 to 13 GPa and an overall adhesion strength of 9 to 13 N.

According to the present disclosure, when forming a coating structure having corrosion resistance even in a plasma or strong corrosive atmosphere on a base member, a relatively low-hardness coating layer is primarily formed on the base member, and a relatively high-hardness coating layer is secondarily formed on the relatively low-hardness coating layer, thereby producing a double-layer composite coating structure. In this way, it is possible to suppress the internal stress of the coating structure formed on the base member. Therefore, it is possible to form a high-density coating structure that is not easily or peeled partially or fully even on a base member having a large area to be coated.

### BRIEF DESCRIPTION OF THE DRAWINGS

FIG. 1 is a flowchart illustrating a thin film stress control-based coating method for large-area coating, according to one embodiment of the present disclosure;

FIG. 2 is a cross-sectional view illustrating a thin film stress control-based composite coating structure suitable for large-area coating, according to one embodiment of the present disclosure;

FIG. 3 is a graph showing the data of physical properties depending on a thickness ratio between coating layers of a large-area composite coating structure according to one embodiment of the present disclosure; and

FIG. 4 is a table including SEM images and thin film surface images of respective large-area composite coating structures in each of which a thickness ratio between coating layers differs, according to one embodiment of the present disclosure.

### DESCRIPTION OF THE PREFERRED EMBODIMENTS

Hereinafter, a thin film stress control-based coating method for large-area coating, according to an embodiment of the present disclosure, will be described in detail. In addition, a coating structure produced using the coating method of the present disclosure will be described.

The present disclosure may be embodied in many forms and may have various embodiments. Thus, specific embodiments will be illustrated in the accompanying drawings and described in detail below. While specific embodiments of the invention will be described herein below, they are only illustrative purposes and should not be construed as limiting to the present disclosure. Accordingly, the present disclosure should be construed to cover not only the specific embodiments but also cover all modifications, equivalents, and substitutions that fall within the spirit and technical scope of the present disclosure. Throughout the drawings, like elements are denoted by like reference numerals. In the accompanying drawings, the dimensions of the structures are larger than actual sizes for clarity of the present disclosure.

Terms “first”, “second”, etc. used in the specification may be used to describe various components, but the components are not to be construed as being limited to the terms. These terms are used only for the purpose of distinguishing a component from another component. For example, a first component may be referred as a second component, and the second component may be also referred to as the first component.

The terminology used herein is for the purpose of describing particular embodiments only and is not intended to be limiting. As used herein, the singular forms “a”, “an”, and “the” are intended to include the plural forms as well unless the context clearly indicates otherwise. It will be further understood that the terms “comprise”, “include”, or “have” when used in this specification specify the presence of stated features, regions, integers, steps, operations, elements and/or components, but do not preclude the presence or addition of one or more other features, regions, integers, steps, operations, elements, components and/or combinations thereof.

In addition, unless otherwise defined, all terms including technical and scientific terms used herein have the same meaning as commonly understood by those who are ordinarily skilled in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Thin Film Stress Control-Based Coating Method for Large-Area Coating

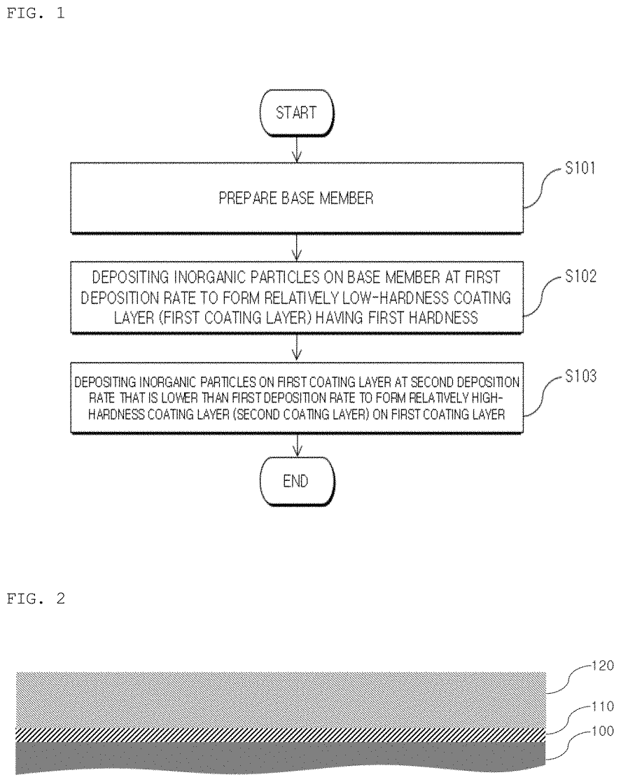

FIG. 1 is a flowchart illustrating a thin film stress control-based coating method for large-area coating, according to one embodiment of the present disclosure.

Referring to FIG. 1, the thin film stress control-based coating method for large-area coating, according to one embodiment of the present disclosure, will be described.

First, in step S101, a base member is prepared. The base member includes at least one selected from among oxides, fluorides, fluorinated oxides, nitrides, oxynitrides, and carbides of at least one selected from among Al, Y, W, Zn, Si and Mo.

Next, in step S102, a first coating layer having a first hardness that is relatively low is formed on the base member by depositing inorganic particles on the prepared base member at a first deposition rate. The inorganic particles are particles of at least one material selected from among oxides, fluorides, fluorinated oxides, nitrides, oxynitrides, and carbides of at least one metal selected from among Al, Y, Ti, W, Zn, Si, Mo, and Mg.

In step S103, a second coating layer having a second hardness that is relatively high is formed on the first coating layer by depositing inorganic particles on the first coating layer at a second deposition rate that is lower than the first deposition rate.

The first coating layer and the second coating layer may be formed through a deposition method such as plasma chemical vapor deposition, sputtering deposition, or electron beam deposition.

The coating method of the present disclosure enables formation of a large-area coating film that is not easily peeled off. In the present disclosure, the term “large area” means that the area to be coated is 78.5 cm² or larger. The diameter and area of the base member that can be coated with a corrosion-resistive coating film that can be formed by the coating method of the present disclosure may be respectively in a range of 10 to 80 cm and a range of 78.5 to 5,024 cm².

On the other hand, when the total thickness of the coating structure including the first coating layer and the second coating layer is within a range of 1 to 20 μm, the coating structure can be reliably formed. The proportion of the thickness of the first coating layer with respect to the total thickness of the overall coating structure including the first and second coating layers may be about 5% to 50%, and the proportion of the thickness of the second coating layer may be 50% to 95%. The thickness ratio of the first coating layer and the second coating ratio may be adjusted with in a range of 1:1 to 1:19.

In addition, when the first coating layer and the second coating layer are formed, the process temperature is in a range of 100° C. to 600° C. and more preferably in a range of 100° C. to 300° C.

On the other hand, as described above, in the present disclosure, the first coating layer may be a relatively low-hardness coating layer, and the second coating layer is a relatively high-hardness coating layer. To form the first and second coating layers that differ in hardness, the present disclosure uses a method of varying the deposition rate.

When the deposition rate of a coating layer is relatively high, the hardness of the coating layer is reduced and the adhesion strength of the coating layer is increased. Conversely, when the deposition rate of a coating layer is relatively low, the hardness of the coating layer is increased and the adhesion strength is reduced.

In the present disclosure, the first coating layer is formed at a deposition rate of 2 to 5 Å/sec.

Here, when the deposition rate of the first coating layer is less than 2 Å/sec, the likelihood that the coating layer will be peeled off is high due to an increase in the hardness and a decrease in the adhesion strength of the first coating layer although the relatively hard second coating layer is subsequently famed. On the other hand, when the deposition rate exceeds 5 Å/sec, since the first coating layer is soft, the first coating layer cannot provide sufficient adhesion between the base member and the second coating layer. Therefore, the entire coating structure is likely to be lifted and peeled off. In addition, when the hardness of the first coating layer is insufficient, there is a problem in that the overall hardness of the double-layer coating structure including the second coating layer is lowered.

In addition, in the present disclosure, after the first coating layer having of a relatively low hardness is formed, the second coating layer is deposited at a deposition rate of 0.5 to 1.5 Å/sec.

Here, when the deposition rate of the second coating layer is lower than 0.5 Å/sec, there is a problem in that the process productivity of the coating structure is deteriorated due to the slow coating speed. On the other hand, when the deposition rate exceeds 1.5 Å/sec, since the hardness of the second coating layer becomes similar to that of the first coating layer, the advantage of the double-layer coating structure described above cannot be obtained.

On the other hand, aside from the adjustment of the deposition rate for each of the first and second coating layers, the thin film stress control-based coating method for large-area coating, according to the present disclosure may control the electric power applied to an ion-assisted deposition apparatus used for the deposition of the first and second coating layers to adjust the hardness of each of the first and second coating layers. The lower the applied electric power, the lower the hardness of the coating layer, whereas the higher the applied power, the higher the hardness of the coating layer.

In the present disclosure, the electric power applied to the ion-assisted deposition apparatus during the formation of the first coating layer is in a range of 200 to 750 W and preferably in a range of 500 to 700 W.

In the present disclosure, the electric power applied to the ion-assisted deposition apparatus during the formation of the second coating layer is in a range of 800 to 1500 W and preferably in a range of 900 to 1000 W.

In addition, when forming the first coating layer and the second coating layer, at least one gas selected from among Ar, O₂ and N₂ may be used, and the gas is supplied at a flow rate of 5 to 100 sccm.

The first coating layer and the second coating layer prepared through the method described above have both the same cubic crystalline phase. Since the crystalline phase of the first coating layer is the same as that of the second coating layer, although the first coating layer and the second coating layer differ in hardness, the adhesion between the two layers is increased. When the crystal phases of the two layers are different, the separation of the two layers may occur due to the lattice mismatching.

On the other hand, in the present disclosure, regarding an optimal thickness ratio between the first coating layer and the second coating layer in the composite coating structure, the proportion of the thickness of the first coating layer with respect to the total thickness of the overall coating structure is about 10% to 20%, and the proportion of the thickness of the second coating layer is about 80% to 90%. That is, the thickness ratio of the first coating layer and the second coating ratio is preferably within a range of 1:9 to 1:4.

When the composite coating structure composed of the first coating layer and the second coating layer is formed to have an optimal thickness ratio within that range, the overall XRD crystallization ratio of the composite coating structure becomes about 80% to 84%. When the XRD crystallization ratio of the entire coating layer is less than 80%, there is a risk that the overall hardness of the coating layer is insufficient. Conversely, when it exceeds 84%, since the number of grain boundaries of the crystals increases, the internal stress of the coating layer becomes larger than the adhesion between the base member and the coating layer, resulting in an increase in likelihood that the first coating layer is peeled off.

In the present disclosure, the first coating layer and the second coating layer are formed to have a hardness of 5 to 8 GPa and a hardness of 10 to 13 GPa, respectively. In addition, the first coating layer and the second coating layer are formed to have an adhesion strength of 10 to 13 N and an adhesion strength of 6 to 8 N, respectively.

When the composite coating structure composed of the first coating layer and the second coating layer is formed to have an optimal thickness ratio, the overall hardness and the overall adhesion strength of the composite coating structure fall with a range of 8 to 13 GPa and a range of 9 to 13 N, respectively.

Thin Film Stress Control-Based Composite Coating Structure Suitable for Large-Area Coating

FIG. 2 is a cross-sectional view illustrating a thin film stress control-based composite coating structure suitable for large-area coating, according to one embodiment of the present disclosure.

Referring to FIG. 2, a thin film stress control-based coating structure suitable for large-area coating, according to an embodiment of the present disclosure, has a structure in which a first coating layer that is a relatively low-hardness layer is formed on a base member and a second coating layer that is a relatively high-hardness layer is formed on the first coating layer.

The base member includes at least one selected from among oxides, fluorides, fluorinated oxides, nitrides, oxynitrides, and carbides of at least one selected from among Al, Y, W, Zn, Si and Mo.

The first coating layer and the second coating layer are made from inorganic particles including at least one material selected from among oxides, fluorides, fluorinated oxides, nitrides, oxynitrides, and carbides of at least one selected from among Al, Y, Ti, W, Zn, Si, Mo, and Mg.

The overall thickness of the composite coating structure including the first coating layer and the second coating layer is within a range of 1 to 20 μm. The proportion of the thickness of the first coating layer with respect to the overall thickness of the composite coating structure including the first and second coating layers is about 5% to 50%, and the proportion of the thickness of the second coating layer is about 50% to 95%. The thickness ratio of the first coating layer and the second coating ratio may be adjusted with in a range of 1:1 to 1:19.

On the other hand, in the present disclosure, regarding an optimal thickness ratio between the first coating layer and the second coating layer in the composite coating structure, preferably, the proportion of the thickness of the first coating layer with respect to the total thickness of the composite coating structure is about 10% to 20%, and the proportion of the thickness of the second coating layer is preferably about 80% to 90%. That is, the optimum thickness ratio of the first coating layer and the second coating ratio is preferably within a range of 1:9 to 1:4.

In addition, in the present disclosure, the first coating layer and the second coating layer prepared through the method described above have the same cubic crystalline phase.

When the composite coating structure composed of the first coating layer and the second coating layer is formed to have the optimal thickness ratio, the overall XRD crystallization ratio of the composite coating structure becomes about 80% to 84%.

In addition, in the composite coating structure according to the present disclosure, the first coating layer has a hardness in a range of 5 to 8 GPa and an adhesion of 10 to 13 N, and the second coating layer has a hardness in a range of 10 to 13 GPa and an adhesion strength of 6 to 8 N. When the composite coating structure composed of the first coating layer and the second coating layer is formed to have the optimal thickness ratio, the overall hardness and the overall adhesion strength of the composite coating structure fall within a range of 8 to 13 GPa and a range of 9 to 13 N, respectively.

Hereinafter, a thin film stress control-based coating method for large-area coating, according to one embodiment of the present disclosure, and a composite coating structure manufactured will be described in more detail with reference to specific examples. The examples described below are presented only to help understanding of the present disclosure, and thus the scope of the present disclosure should not be construed to be limited thereto.

### EXAMPLE 1

A first coating layer having a relatively low hardness was formed on an aluminum oxide base member having a diameter of 50 cm² and an area of 2,000 cm² using the coating method described with reference to FIG. 1 at a deposition rate of 3.5 Å/sec. Next, a second coating layer having a relatively high hardness was formed on the first coating layer at a deposition rate of 1.0 Å/sec. Electric power applied to an ion-assisted deposition apparatus was 500 W for the first coating layer and 900 W for the second coating layer. In the resulting composite coating structure composed of the first coating layer and the second coating layer, the thickness ratio of the first coating layer and the second coating layer was 20:80. An e-beam deposition method was used as a specific method, and yttrium oxide powder was used as a deposition material for the formation of the first and second coating layers.

### EXAMPLE 2

A composite coating structure was famed in the same manner as in Example 1, except that the thickness ratio of the first coating layer and the second coating layer was 10:90.

### COMPARATIVE EXAMPLE 1

A composite coating structure was famed in the same manner as in Example 1, except that the thickness ratio of the first coating layer and the second coating layer was 100:0.

### COMPARATIVE EXAMPLE 2

A composite coating structure was foamed in the same manner as in Example 1, except that the thickness ratio of the first coating layer and the second coating layer was 50:50.

### COMPARATIVE EXAMPLE 3

A composite coating structure was foamed in the same manner as in Example 1, except that the thickness ratio of the first coating layer and the second coating layer was 30:70.

### COMPARATIVE EXAMPLE 4

A composite coating structure was foiled in the same manner as in Example 1, except that the thickness ratio of the first coating layer and the second coating layer was 5:95.

### COMPARATIVE EXAMPLE 5

A composite coating structure was foiled in the same manner as in Example 1, except that the thickness ratio of the first coating layer and the second coating layer was 0:100.

### EXPERIMENTAL EXAMPLE 1

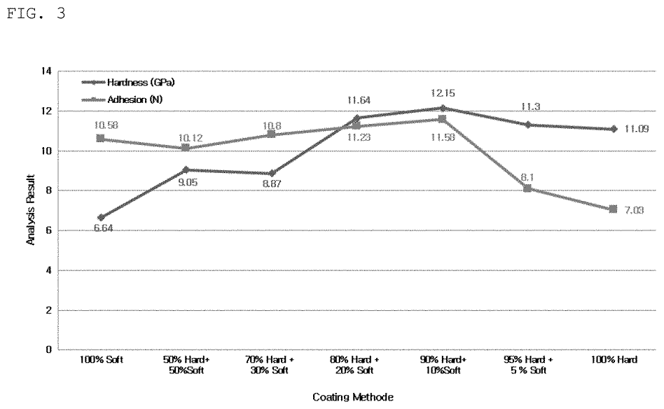

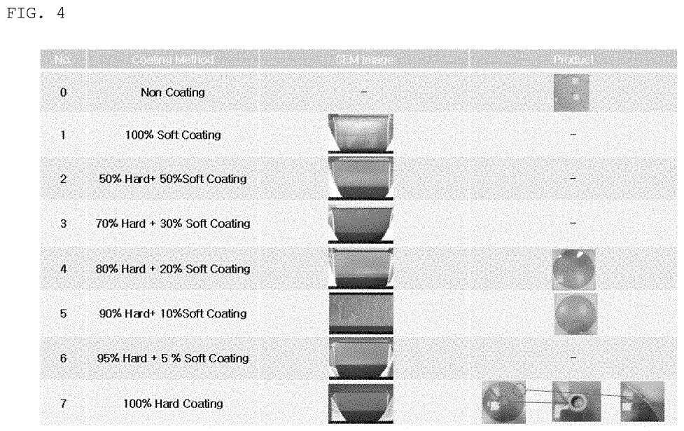

The hardness and adhesion of the coating structures prepared according to Examples 1 to 2 and Comparative Examples 1 to 5 were measured. A Ti-750 model manufactured by Hysitron Inc. was used for hardness analysis, and a , and for adhesion analysis, a micro scratch tester MST manufactured by Anton Paar GmbH was used for adhesion test. The analysis results are shown in FIG. 3 and Table 1.

TABLE 1

| | Thickness Ratio | | | | |
|---|---|---|---|---|---|
| | First | Second | | | |
| | coating | coating | | | |
| | layer | layer | Total | | |
| | Thickness | Thickness | thickness | Hardness | Adhesion |
| No. | (%) | (%) | (μm) | (GPa) | (N) |
| Comparative | 100 | — | 10 ± 1 μm | 6.64 | 10.58 |
| Example 1 | | | | | |
| Comparative | 50 | 50 | | 9.05 | 10.12 |
| Example 2 | | | | | |
| Comparative | 30 | 70 | | 8.87 | 10.8 |
| Example 3 | | | | | |
| Example 1 | 20 | 80 | | 11.64 | 11.23 |
| Example 2 | 10 | 90 | | 12.15 | 11.58 |
| Comparative | 5 | 95 | | 11.3 | 8.1 |
| Example 4 | | | | | |
| Comparative | — | 100 | | 11.09 | 7.03 |
| Example 5 | | | | | |

As shown in FIG. 1 and Table 1, when the thickness ratio of the first coating layer having a relatively low hardness and the second coating layer having a relatively high hardness was in a range of 20:80 to 10:90, excellent hardness and adhesion properties were exhibited.

### EXPERIMENTAL EXAMPLE 2

SEM images and surface images of the coating structures prepared according to Examples 1 to 2 and Comparative Examples 1 to 5 are shown in Table 4.

As shown in FIG. 4, in the case of Comparative Example 5 in which only a relatively high-hardness coating layer (i.e., second coating layer) was formed, it was observed that the coating layer was peeled at the edge of the base member because the internal stress of the coating layer was stronger than the adhesion between the base member and the coating layer. That is, when only a high-hardness coating layer is formed on a base member with a surface large area to be coated, there is a problem in that that the coating layer may be partially peeled at the edges of the base member or lifted off from the entire surface of the base member.

On the other hand, in the case of Comparative Example 1 in which only a low-hardness coating layer (i.e., first coating layer) was formed to relieve the internal stress of the coating layer, peeling did not occur, but there was a problem in that the hardness of the coating layer was insufficient.

To address the problems of a coating structure made from only a high-hardness coating layer and a coating structure made from only a low-hardness coating layer, the thickness ratio of two coating layers in each of the composite coating structures prepared according to the examples and comparative examples were varied and the properties of the composite coating structures were observed.

When the proportion of the thickness of the second coating layer was 95% with respect to the overall thickness of the composite coating structure, the hardness was slightly increased, but the adhesion was slightly low. On the other hand, when the proportion was 50% or 70%, the adhesion was increased to a satisfiable level, but an increase in the hardness was insignificant. When the proportions were 80% and 90%, respectively, physical properties including hardness and adhesion were improved to satisfiable levels. That is, when the proportion of the thickness of the second coating layer was in a range of 80% to 90%, it was confirmed that reliable composite coating structures that had strong corrosion resistance and were hardly peeled off were formed even when the composite coating structure was applied to a large-area base member.

That is, the peeling of coating was not observed in the cases where the thickness ratio of the first coating layer which is a relatively low-hardness layer and the second coating layer which is a relatively high-hardness layer was within a range of 20:80 to 10:90, and the composite coating structures exhibited satisfiable hardness and good adhesion.

### EXPERIMENTAL EXAMPLE 3

The crystallinity or amorphousness of each of the coating structures prepared according to Examples 1 to 2 and Comparative Examples 1 to 5 was measured using X-Ray Diffraction (XRD) equipment.

The measurement results are shown in Table 2 below.

TABLE 2

| | Thickness ratio | | | |
|---|---|---|---|---|
| | First | Second | | |
| | coating | coating | | |
| | layer | layer | | |
| | Thickness | Thickness | Crystallinity | Amorphous |
| No. | (%) | (%) | (%) | (%) |
| Comparative | 100 | — | 74.5 | 25.5 |
| Example 1 | | | | |
| Comparative | 50 | 50 | 79.3 | 20.7 |
| Example 2 | | | | |
| Comparative | 30 | 70 | 78.5 | 21.5 |
| Example 3 | | | | |
| Example 1 | 20 | 80 | 80.6 | 19.4 |
| Example 2 | 10 | 90 | 83.4 | 16.6 |
| Comparative | 5 | 95 | 85.6 | 14.4 |
| Example 4 | | | | |
| Comparative | — | 100 | 84.1 | 15.9 |
| Example 5 | | | | |

As shown in Table 2, when the thickness ratio of the first coating layer that is a relatively low-hardness layer and the second coating layer that is a relatively high-hardness layer was in a range of 20:80 to 10:90, and the XRD crystallization ratio was found to be within a range of 80 to 84. That is, when the thickness ratio of the first coating layer and the second coating layer is in a range of 20:80 to 10:90, the coating structure can exhibit suitable hardness thereof and good adhesion with the base member.

While the present disclosure has been described with reference to exemplary embodiments illustrated in the accompanying drawings, those skilled in the art will appreciate that the exemplary embodiments are presented only for illustrative purposes. On the contrary, it will be understood that various modifications and equivalents to the exemplary embodiments are possible. Accordingly, the technical scope of the present disclosure should be defined by the following claims.

What is claimed is:

1. A thin film stress control-based coating method for large-area coating, the method comprising:
preparing a base member;
depositing inorganic particles on the base member at a first deposition rate to form a first coating layer as a relatively low-hardness coating layer having a first hardness; and
depositing inorganic particles on the first coating layer at a second deposition rate that is lower than the first deposition rate to form a second coating layer as a relatively high-hardness coating layer having a second hardness that is higher than the first hardness.

2. The method of claim 1, wherein the first coating layer and the second coating layer are formed by plasma chemical vapor deposition, sputtering deposition, or electron-beam deposition.

3. The method of claim 1, wherein the inorganic particles are particles of at least one material selected from among oxides, fluorides, fluorinated oxides, nitrides, oxynitrides, and carbides of at least one metal selected from among Al, Y, Ti, W, Zn, Si, Mo, and Mg.

4. The method of claim 1, wherein the base member has a diameter in a range of 10 to 80 cm and an area in a range of 78.5 to 5,024 cm².

5. The method of claim 1, wherein the base member comprises at least one selected from among oxides, fluorides, fluorinated oxides, nitrides, oxynitrides, and carbides of at least one material selected from among Al, Y, W, Zn, Si and Mo.

6. The method of claim 1, wherein the first coating layer and the second coating layer are formed at a process temperature in a range of 100° C. to 600° C.

7. The method of claim 1, wherein the first coating layer is formed at a deposition rate of 2 to 5 Å/sec, and
the second coating layer is formed at a deposition rate of 0.5 to 1.5 Å/sec.

8. The method of claim 1, wherein electric power applied to an ion-assisted deposition apparatus is in a range of 200 to 750 W when forming the first coating layer, and
electric power is in a range of 800 to 1500 W when forming the second coating layer.

9. The method of claim 1, wherein at least one gas selected from among Ar, 02 and N2 is used to form the first and second coating layers, and the gas is supplied at a flow rate of 5 to 100 sccm.

10. A thin film stress control-based coating structure for large-area coating, the coating structure being manufactured by the method of claim 1.

11. The coating structure comprises:
a first coating layer having a relatively low hardness of 5 to 8 GPa and foiled by depositing inorganic particles on a base member; and
a second coating layer having a relatively high hardness of 10 to 13 GPa and formed by depositing inorganic particles on the first coating layer.

12. The coating structure of claim 11, wherein the base member has a diameter in a range of 10 to 80 cm and an area in a range of 78.5 to 5,024 cm².

13. The coating structure according to claim 11, wherein the base member comprises at least one material selected from among oxides, fluorides, fluorinated oxides, nitrides, oxynitrides, and carbides of at least one material selected from among Al, Y, W, Zn, Si and Mo.

14. The coating structure of claim 11, wherein the inorganic particles are particles of at least one material selected from among oxides, fluorides, fluorinated oxides, nitrides, oxynitrides, and carbides of at least one metal selected from among Al, Y, Ti, W, Zn, Si, Mo, and Mg.

15. The coating structure according to claim 11, wherein the first coating layer and the second coating layer have an overall thickness of 1 to 20 μm in total.

16. The coating structure according to claim 11, wherein the first coating layer and the second coating layer have the same crystalline phase.

17. The coating structure according to claim 11, wherein the first coating layer and the second coating layer have a cubic crystalline phase.

18. The coating structure of claim 11, a proportion of the thickness of the second coating layer with respect to the overall thickness of the coating structure including the first coating layer and the second coating layer is within a range of 80% to 90%.

19. The coating structure of claim 11, wherein the coating structure including the first coating layer and the second coating layer has an XRD crystallization ratio of 80% to 84%.

20. The coating structure of claim 11, wherein the first coating layer has an adhesion of 10 to 13 N, and
the second coating layer has an adhesion of 6 to 8 N.

21. The coating structure of claim 11, wherein the coating structure including the first coating layer and the second coating layer has an overall hardness of 8 to 13 GPa and an overall adhesion of 9 to 13 N.
